(19) United States
(12) Patent Application Publication
(10) Pub. No.: US 2026/0151805 A1
(43) Pub. Date: Jun. 4, 2026

(54) DRAIN CUP MODULE, SUBSTRATE WETTING APPARATUS INCLUDING THE SAME, AND SUBSTRATE PROCESSING METHOD USING THE SAME

(71) Applicant: SAMSUNG ELECTRONICS CO., LTD., Suwon-si (KR)

(72) Inventors: Hyeong-Kwon JEONG, Suwon-si (KR); Hyun-Chul KIM, Suwon-si (KR); Hyunmo KANG, Suwon-si (KR); Ohchel KWON, Suwon-si (KR)

(73) Assignee: SAMSUNG ELECTRONICS CO., LTD., Suwon-si (KR)

(21) Appl. No.: 19/252,660

(22) Filed: Jun. 27, 2025

(30) Foreign Application Priority Data
Nov. 29, 2024 (KR) 10-2024-0174810

(51) Int. Cl. B08B 13/00; B08B 1/52; B08B 1/54; H01L 21/67

(52) U.S. Cl. CPC B08B 13/00; B08B 1/52; B08B 1/54; H10P 72/0408; H10P 72/0414

(57) ABSTRACT

A drain cup module includes a cup body including an outlet at a lower portion thereof, a cleaning liquid sprayer on the cup body, and including an open upper end and an open lower end, and a sealing member between the cup body and the cleaning liquid sprayer, where the sealing member includes an O-ring contacting the cup body and the cleaning liquid sprayer, and having a central axis that intersects a radial direction extending toward an inside of the O-ring, and brushes extending from an inside of the O-ring in the radial direction toward the central axis.

### CROSS-REFERENCE TO RELATED APPLICATIONS

This application is based on and claims priority under 35 U.S.C. § 119 to Korean Patent Application No. 10-2024-0174810, filed on Nov. 29, 2024, in the Korean Intellectual Property Office, the disclosure of which is incorporated by reference herein in its entirety.

### BACKGROUND

The present disclosure relates to a drain cup module, a substrate wetting apparatus including the same, and a substrate processing method using the same.

A semiconductor device may be manufactured through various processes. For example, the semiconductor device may be made through a photo process, an etching process, a deposition process, a plating process, and the like. A wetting process in which a liquid such as a processing liquid is applied on a wafer may be performed during the photo process for manufacturing the semiconductor device. In addition, a drying process in which the liquid applied on the wafer is removed from the wafer may be performed. Various methods may be used in order to apply the liquid on the wafer, or remove the liquid from the wafer.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a drain cup module that may be capable of achieving improved cleaning ability, a substrate wetting apparatus including the same, and a substrate processing method using the same.

One or more example embodiments provide a drain cup module that may be capable of preventing substrate contamination, a substrate wetting apparatus including the same, and a substrate processing method using the same.

Additional aspects will be set forth in part in the description which follows and, in part, will be apparent from the description, or may be learned by practice of the presented embodiments.

According to an aspect of an example embodiment, a drain cup module may include a cup body including an outlet at a lower portion thereof, a cleaning liquid sprayer on the cup body, and including an open upper end and an open lower end, and a sealing member between the cup body and the cleaning liquid sprayer, where the sealing member may include an O-ring contacting the cup body and the cleaning liquid sprayer, and having a central axis that intersects a radial direction extending toward an inside of the O-ring, and brushes extending from an inside of the O-ring in the radial direction toward the central axis.

According to an aspect of an example embodiment, a substrate wetting apparatus may include a wet stage configured to support a substrate, a spray nozzle configured to supply a processing liquid on the substrate, and a drain cup module spaced apart from the wet stage, where the drain cup module may include a cup body including an outlet at a lower portion thereof, a cleaning liquid sprayer on the cup body, and a sealing member between the cup body and the cleaning liquid sprayer, and the spray nozzle may be configured to contact the sealing member.

According to an aspect of an example embodiment, a drain cup module may include a cup body, a cleaning liquid sprayer on the cup body and configured to receive a spray nozzle of a substrate wetting apparatus, an O-ring between the cup body and the cleaning liquid sprayer, the O-ring having a central axis that intersects a radial direction extending toward an inside of the O-ring, and at least one brush extending from an inner circumference of the O-ring toward the central axis of the O-ring, where at least one of the at least one brush may include a groove therein that is configured such that cleaning liquid supplied by the cleaning liquid sprayer flows along the groove and toward the spray nozzle of the substrate wetting apparatus.

According to an aspect of an example embodiment, a substrate processing method may include cleaning a spray nozzle of a substrate wetting apparatus, and processing a substrate, where the cleaning of the spray nozzle may include supplying a cleaning liquid into a drain cup module of the substrate wetting apparatus, moving the spray nozzle along a direction in the drain cup module, and contacting the spray nozzle with a portion of a sealing member of the drain cup module. The method may include repeating the moving of the spray nozzle in and out of the drain cup at least twice. The cleaning of the spray nozzle may include spraying a processing liquid remaining in the spray nozzle. The cleaning of the spray nozzle may be performed before processing the substrate. The cleaning of the spray nozzle may be performed based on an idle time of the substrate wetting apparatus being equal to or greater than a predetermined value.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a substrate processing system according to one or more embodiments;

FIG. 2 is a cross-sectional view illustrating a substrate drying apparatus according to one or more embodiments;

FIG. 3 is a diagram illustrating a super-critical fluid supplier according to one or more embodiments;

FIG. 4 is a perspective view illustrating a substrate wetting apparatus according to one or more embodiments;

FIG. 5 is a cross-sectional view taken along line A-A′ of FIG. 4 illustrating a substrate wetting apparatus according to one or more embodiments;

FIG. 6 is a perspective view illustrating a drain cup module according to one or more embodiments;

FIG. 7 is a cross-sectional view taken along line B-B′ of FIG. 6 illustrating a drain cup module according to one or more embodiments;

FIG. 8 is a perspective view illustrating a sealing member of a drain cup module according to one or more embodiments;

FIG. 9 is a plan view illustrating a sealing member of a drain cup module according to one or more embodiments;

FIG. 10 is a cross-sectional view taken along line C-C′ of FIG. 8 illustrating a sealing member of a drain cup module according to one or more embodiments;

FIG. 11 is an enlarged diagram of region X of FIG. 9 according to one or more embodiments;

FIG. 12 is an enlarged diagram of region Y of FIG. 10 according to one or more embodiments;

FIG. 13 is a perspective view illustrating a sealing member of a drain cupmodule according to one or more embodiments;

FIG. 14 is a flowchart illustrating a substrate processing method according to one or more embodiments; and

FIGS. 15 to 18 are diagrams illustrating a substrate processing method according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

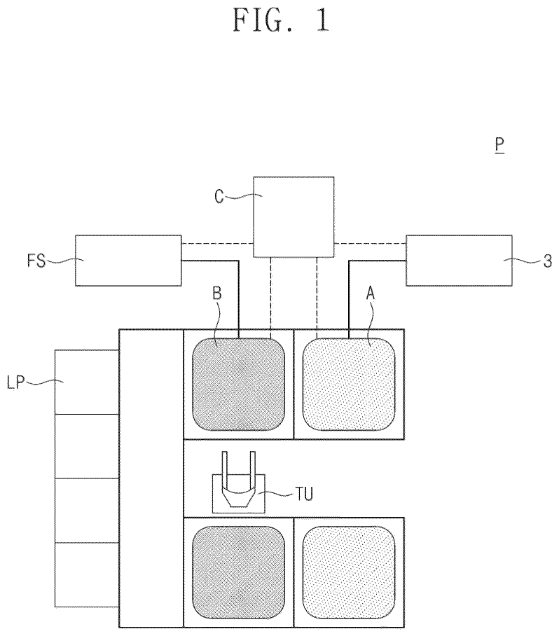

FIG. 1 is a diagram illustrating a substrate processing system according to one or more embodiments.

Referring to FIG. 1, a substrate processing system P may be provided. The substrate processing system P may include apparatuses that process a substrate in a process of manufacturing a semiconductor device. More specifically, the substrate processing system P may include apparatuses that perform a wetting process and a drying process for the substrate. For example, the substrate processing system P may wet the substrate by spraying a liquid, or the like, on the substrate, and may dry and clean the substrate by removing the liquid, or the like, from the substrate. That is, the substrate processing system P may be a system including a plurality of substrate processing apparatuses in order to clean the substrate.

According to one or more embodiments, the substrate processing system P may spray a processing liquid on the substrate which has undergone an extreme ultraviolet (EUV) exposure process. In addition, the substrate processing system P may dry the processing liquid on the substrate. The substrate may correspond to a semiconductor wafer. The semiconductor wafer may include a silicon (Si) wafer, but embodiments are not limited thereto. The substrate processing system P may include load ports LP, a substrate drying apparatus A, a substrate wetting apparatus B, a controller C, a processing liquid supplier FS, a super-critical fluid supplier 3 and a transfer apparatus TU.

The load ports LP may be ports on which the substrate is loaded. For example, the substrate may be loaded on the load ports LP in a form in which the substrate is stored in a front opening unified pod (FOUP). The substrate in the FOUP may be in a state after having undergone various processes for manufacturing the semiconductor device. A number of the load ports LP may be variously provided.

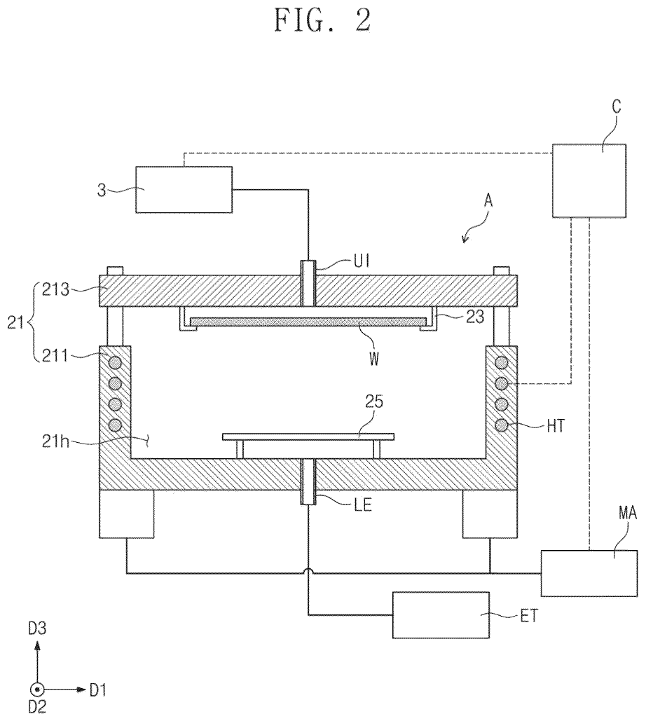

The substrate drying apparatus A may be an apparatus that dries the substrate. The substrate drying apparatus A may dry and/or clean the substrate passing through the substrate wetting apparatus B. According to one or more embodiments, two substrate drying apparatuses A may be provided. In this case, the two substrate drying apparatuses A may be disposed so as to face each other. Description of the substrate drying apparatus A will be made with reference to FIG. 2 in detail.

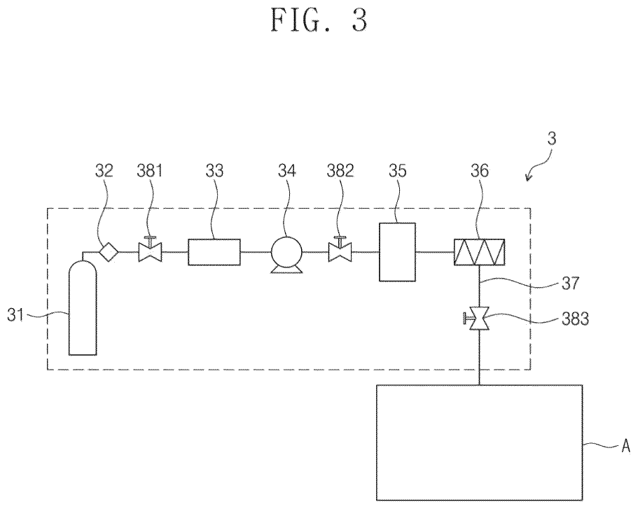

The super-critical fluid supplier 3 may supply a fluid to the substrate drying apparatus A. More specifically, the super-critical fluid supplier 3 may supply a super-critical fluid sprayed inside the substrate drying apparatus A. For example, the super-critical fluid supplier 3 may supply carbon dioxide (CO₂) being in a super-critical fluid (SCF) state to the substrate drying apparatus A. Description of the super-critical fluid supplier 3 will be made later with reference to FIG. 3 in detail.

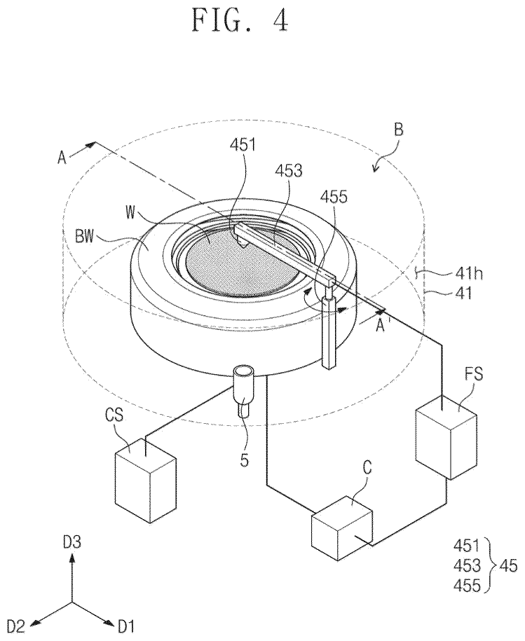

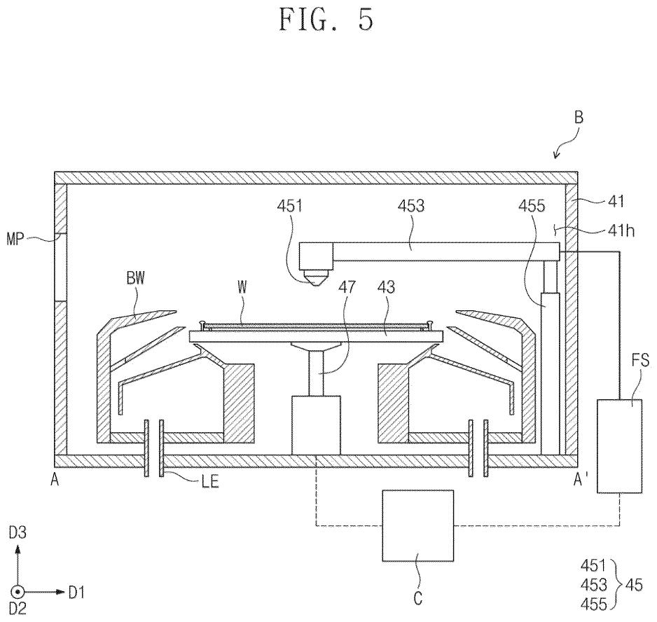

The substrate wetting apparatus B may be an apparatus that performs a wetting process for the substrate. The substrate wetting apparatus B may supply a space in which the wetting process is performed on the substrate. In this case, two substrate wetting apparatuses B may be disposed so as to face each other. Description of the substrate wetting apparatus B will be made later with reference to FIGS. 4 and 5 in detail.

The processing liquid supplier FS may supply the processing liquid to the substrate wetting apparatus. For example, the processing liquid supplier FS may include a fluid tank, a pump and the like. The processing liquid may include various chemicals and/or water. More specifically, the processing liquid may include a developer, an isopropyl alcohol (IPA), and/or the like.

The transfer apparatus TU may be disposed adjacent to the substrate drying apparatus A and the substrate wetting apparatus B. The transfer apparatus TU may transfer the substrate. For example, the transfer apparatus TU may transfer the substrate loaded on the load ports LP to the substrate wetting apparatus B. In addition, the transfer apparatus TU may pull the substrate from the substrate wetting apparatus B and may transfer the substrate to the substrate drying apparatus A. The transfer apparatus TU may include an actuator such as a motor. One transfer apparatus TU may be provided, but embodiments are not limited thereto.

The controller C may control the substrate drying apparatus A and the substrate wetting apparatus B. For example, the controller C may control the super-critical fluid supplier 3 to control a dried degree of the substrate. The controller C may control the processing liquid supplier FS to control an application degree of the processing liquid on the substrate. More specifically, the controller C may control an amount of the super-critical fluid supplied into the substrate drying apparatus A, and an amount of the processing liquid supplied into the substrate wetting apparatus B.

FIG. 2 is a cross-sectional view illustrating a substrate drying apparatus according to one or more embodiments.

Referring to FIG. 2, the substrate drying apparatus A may be provided. The substrate drying apparatus A may perform a drying process for a substrate W. For example, the drying process may be a process of removing the processing liquid applied on the substrate W from the substrate W. The super-critical fluid may be used in order to remove the processing liquid, or the like. The substrate drying apparatus A may include a drying chamber 21, a drying heater HT, a drying stage 23, a blocking plate 25, a chamber driver MA, a discharge tank ET, and the like.

The drying chamber 21 may provide a drying space 21h. The drying chamber 21 may include a lower housing 211 and an upper housing 213 on the lower housing 211. The lower housing 211 and the upper housing 213 may be spaced apart from each other. The drying space 21h may be provided in the lower housing 211. The lower housing 211 may be configured so as to move in a vertical direction. For example, the lower housing 211 may be coupled with the upper housing 213 by the chamber driver MA. The lower housing 211 and the upper housing 213 may be coupled with each other so that the drying space 21h may be isolated from an outside thereof.

The upper housing 213 may supply an upper inflow UI. The upper inflow UI may be connected to the super-critical fluid supplier 3. The super-critical fluid may be supplied from the super-critical fluid supplier 3 to the drying space 21h through the upper inflow UI. The lower housing 211 may provide a lower outlet LE. The lower outlet LE may be connected to the discharge tank ET. The super-critical fluid may be discharged to an outside the drying chamber 21 through the lower outlet LE.

The drying heater HT may be located in the drying chamber 21. The drying heater HT may heat the drying space 21h to maintain the drying space 21h at a constant temperature. Accordingly, the super-critical fluid introduced to the drying space 21h may maintain a super-critical state.

The drying stage 23 may be coupled with the upper housing 213. The drying stage 23 may be connected to a lower end of the upper housing 213. The drying stage 23 may support and fix the substrate W. For example, the drying stage 23 may be disposed such that an upper surface of the substrate W in the drying stage 23 is parallel to a first direction D1 and a second direction D2.

As described herein, the first direction D1 and the second direction D2 may intersect each other. A third direction D3 may intersect the first direction D1 and the second direction D2. For example, the first direction D1, the second direction D2 and the third direction D3 may be perpendicular to each other. The first direction D1 and the second direction D2 may be referred to as horizontal directions, and the third direction D3 may be referred to as a vertical direction.

The blocking plate 25 may be connected to the lower housing 211. The blocking plate 25 may be spaced by a predetermined interval apart from the lower outlet LE. The blocking plate 25 may block the super-critical fluid from flowing. For example, the blocking plate 25 may hinder the super-critical fluid from flowing out to the lower outlet LE. Accordingly, the super-critical fluid may remain in the drying space 21h for a long time.

The chamber driver MA may be connected to the lower housing 211. The chamber driver MA may move the lower housing 211 in the vertical direction. The chamber driver MA may couple the lower housing 211 to the upper housing 213, or may separate the lower housing 211 from the upper housing 213. For example, the chamber driver MA may include an actuator such as a motor.

FIG. 3 is a diagram illustrating a super-critical fluid supplier according to one or more embodiments.

Referring to FIG. 3, the super-critical fluid supplier 3 may include a drying fluid supply source 31, a drying fluid line 37, a supply filter 32, a first valve 381, a condenser 33, a pump 34, a second valve 382, a tank 35, a heater 36 and a third valve 383.

The drying fluid supply source 31 may supply a drying fluid. More specifically, the drying fluid supply source 31 may store and supply a fluid (e.g., the super-critical fluid) in a gaseous state. The drying fluid supplied by the drying fluid supply source 31 may move along the drying fluid line 37. For example, the drying fluid line 37 may be a path through which the drying fluid supplied by the drying fluid supply source 31 is introduced to the substrate drying apparatus A.

According to one or more embodiments, the fluid (e.g., the super-critical fluid) may be carbon dioxide (CO₂). In this case, the drying fluid supply source 31 may store the carbon dioxide (CO₂) in the gaseous state. The carbon dioxide (CO₂) supplied by the drying fluid supply source 31 may have a temperature of about 10° C. to about 30° C. In addition, the carbon dioxide (CO2) supplied by the drying fluid supply source 31 may have a pressure of about 4 MPa to about 6 MPa.

The supply filter 32 may be located on the drying fluid line 37. The supply filter 32 may remove a foreign matter in the drying fluid. The first valve 381 may control moving of the drying fluid by opening and closing the drying fluid line 37 between the supply filter 32 and the condenser 33.

The condenser 33 may cool the drying fluid, supplied by the drying fluid supply source 31, in the gaseous state. Accordingly, the drying fluid in the gaseous state may be liquefied by the condenser 33. When the fluid is carbon dioxide (CO₂), the liquefied carbon dioxide (CO₂) may have a temperature of about 0° C. to about 6° C. In addition, the liquefied carbon dioxide (CO₂) may have a pressure of about 4 MPa to about 6 MPa.

The pump 34 may increase the pressure of the liquefied drying fluid. When the fluid is carbon dioxide (CO₂), the pressure of the liquefied carbon dioxide (CO₂) may be increased to about 15 MPa to about 25 MPa by the pump 34. In addition, the liquefied carbon dioxide (CO₂) may pass through the pump 34 so that a temperature thereof increases to about 15° C. to about 25° C.

The second valve 382 may control moving of the drying fluid by opening and closing the drying fluid line 37 between the pump 34 and the tank 35. The tank 35 may store the drying fluid compressed by the pump 34.

The heater 36 may heat the drying fluid moving along the drying fluid line 37. The third valve 383 may control moving of the drying fluid by opening and closing the drying fluid line 37 between the heater 36 and the substrate drying apparatus A. The drying fluid may pass through the third valve 383 to be introduced to an inside of the substrate drying apparatus A. When the fluid is carbon dioxide (CO₂), the carbon dioxide (CO₂) may be changed into a super-critical state by the heater 36. The carbon dioxide (CO₂) in the super-critical state may have a high temperature and a high pressure. For example, the carbon dioxide (CO₂) in the super-critical state may have a temperature of about 60° C. to about 90° C. In addition, the carbon dioxide (CO₂) in the super-critical state may have a pressure of about 15 MPa to about 25 MPa.

FIG. 4 is a perspective view illustrating a substrate wetting apparatus according to one or more embodiments. FIG. 5 is a cross-sectional view taken along line A-A′ of FIG. 4 illustrating a substrate wetting apparatus according to one or more embodiments.

Referring to FIGS. 4 and 5, the substrate wetting apparatus B may be provided. The substrate wetting apparatus B may perform a wetting process for the substrate W. For example, the wetting process may be a process of applying a liquid such as the processing liquid on the substrate W. The substrate wetting apparatus B may include a wetting chamber 41, a wetting stage 43, a processing liquid sprayer 45, a rotational axis 47, a bowl BW and a drain cup module 5.

The wetting chamber 41 may provide a wetting space 41h therein. A wetting process for the substrate W may be performed in the wetting space 41h. A path MP through which the substrate W moves may be provided on one sidewall of the wetting chamber 41. A lower outlet LE through which the processing liquid is discharged may be provided on a lower portion of the wetting chamber 41. The lower outlet LE may be connected to the bowl BW, and may be provided in plurality. In addition, an outlet connected to the drain cup module 5 may be provided on the lower portion of the wetting chamber 41.

The wetting stage 43 may be located in the wetting space 41h of the wetting chamber 41. More specifically, the wetting stage 43 may be located in the bowl BW. For example, the substrate W inserted into the substrate wetting apparatus B may be disposed on the wetting stage 43. The wetting stage 43 may support and fix the substrate W. In addition, the wetting stage 43 may be configured so as to rotate the substrate W.

The processing liquid sprayer 45 may be located in the wetting space 41h of the wetting chamber 41, and may be disposed spaced apart from the bowl BW. The processing liquid sprayer 45 may be connected to the processing liquid supplier FS. For example, the processing liquid sprayer 45 may receive the processing liquid from the processing liquid supplier FS to spray the processing liquid onto the substrate. The processing liquid sprayer 45 may include a spray nozzle 451, a dispenser line 453, a nozzle mover 455 and the like.

The spray nozzle 451 may be located on the wetting stage 43, or in the drain cup module 5. The spray nozzle 451 may be located on the wetting stage 43 during the wetting process. In this case, the spray nozzle 451 may spray the processing liquid toward the substrate W disposed on the wetting stage 43. The spray nozzle 451 may be located in the drain cup module 5 during a standby process of not performing the wetting process. In this case, a cleaning process for the spray nozzle 451 may be performed. For this, the spray nozzle 451 may be configured so as to move in a horizontal direction and a vertical direction.

The dispenser line 453 may be connected to the spray nozzle 451 and the processing liquid supplier FS. For example, the dispenser line 453 may have a form in which the dispenser line 453 extends in one direction. The dispenser line 453 may have, therein, a path through which the processing liquid moves. That is, the processing liquid supplied by the processing liquid supplier FS may move through the dispenser line 453 to the spray nozzle 451. In addition, the dispenser line 453 may be connected to the nozzle mover 455. The dispenser line 453 may be configured so as to move with the spray nozzle 451 in the horizontal direction and the vertical direction.

The nozzle mover 455 may be coupled to a lower portion of the wetting chamber 41. The nozzle mover 455 may move the spray nozzle 451 and the dispenser line 453 in the wetting space 41h of the wetting chamber 41 in the horizontal direction and the vertical direction. For this, the nozzle mover 455 may include an actuator such as a motor.

The rotational axis 47 may be coupled to a lower portion of the wetting stage 43 in the bowl BW. The rotational axis 47 may be electrically connected to the controller C. For example, the rotational axis 47 may receive an electrical signal from the controller C to rotate the wetting stage 43. For this, the rotational axis 47 may include a motor, or the like. Accordingly, the substrate W on the wetting stage 43 may be rotated clockwise or counterclockwise by the rotational axis 47.

The bowl BW may surround the wetting stage 43 and the rotational axis 47. The bowl BW may be configured so as to gather the processing liquid pushed out from the wetting stage 43. The gathered processing liquid may be discharged to the outside through the lower outlet LE connected to the bowl BW.

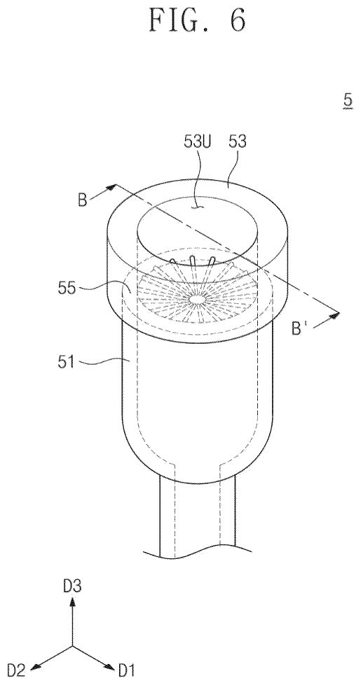

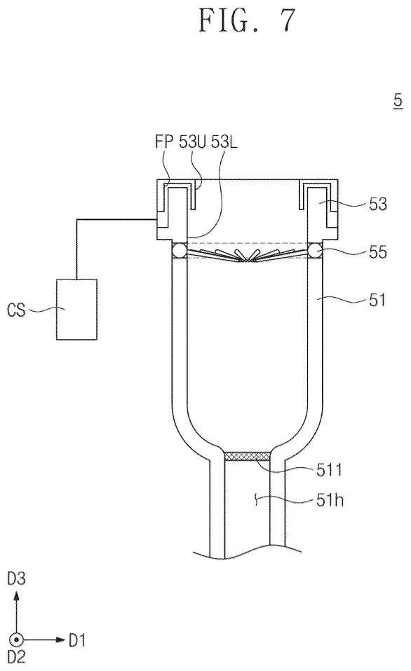

The drain cup module 5 may be located in the wetting space 41h of the wetting chamber 41. The drain cup module 5 may be disposed to be spaced apart from the processing liquid sprayer 45 and the bowl BW in the wetting chamber 41. The drain cup module 5 may be coupled to the lower portion of the wetting chamber 41. The drain cup module 5 may clean the spray nozzle 451 of the processing liquid sprayer 45. In addition, the drain cup module 5 may process the processing liquid staying in the spray nozzle 451. Description for the drain cup module 5 will be made later with reference to FIGS. 6 and 7 in detail.

The cleaning liquid supplier CS may be connected to the drain cup module 5. The cleaning liquid supplier CS may supply a cleaning liquid into the drain cup module 5. More specifically, the cleaning liquid supplier CS may supply the cleaning liquid for cleaning the spray nozzle 451. For example, the cleaning liquid may include DI water, or the like.

FIG. 6 is a perspective view illustrating a drain cup module according to one or more embodiments. FIG. 7 is a cross-sectional view taken along line B-B′ of FIG. 6 illustrating a drain cup module according to one or more embodiments.

Referring to FIGS. 6 and 7, the drain cup module 5 may be provided. The drain cup module 5 may be an apparatus for cleaning the spray nozzle 451 of the processing liquid sprayer 45 described with reference to FIG. 4. The drain cup module 5 may include a cup body 51, a cleaning liquid sprayer 53 on the cup body 51, and a sealing member 55 between the cup body 51 and the cleaning liquid sprayer 53.

The cup body 51 may have a structure in which an inside thereof is empty in order to accommodate the processing liquid sprayed from the spray nozzle 451. For example, the cup body 51 may have a cup shape. A diameter of the cup body 51 may be smaller in an upper portion of the cup body 51 than in a lower portion of the cup body 51, but embodiments are not limited thereto. Furthermore, the cup body 51 may have a tapered shape in which a diameter of the cup body 51 gradually decreases from the upper portion of the cup body 51 to the lower portion of the cup body 51. The cup body 51 may provide (e.g., include) an outlet 51h at a lower portion thereof. The processing liquid may be discharged to an outside thereof through the outlet 51h of the cup body 51.

According to one or more embodiments, a mesh 511 may be further provided inside the cup body 51. The mesh 511 may be located on the outlet 51h of the cup body 51. The mesh 511 may pass through the process liquid facing the outlet 51h. In addition, the mesh 511 may prevent the processing liquid from scattering to an inside the cup body 51.

The cleaning liquid sprayer 53 may have an opened structure in which the spray nozzle 451 of FIG. 4 passes therethrough. For example, the cleaning liquid sprayer 53 may have an open upper end 53U and an open lower end 53L. That is, the upper end 53U and the lower end 53L of the cleaning liquid sprayer 53 may have a hole penetrating the cleaning liquid sprayer 53 in the third direction D3. Accordingly, the spray nozzle 451 of FIG. 4 may pass through the cleaning liquid sprayer 53 to be inserted into an inside of the cup body 51.

The cleaning liquid sprayer 53 may have a fluid path FP therein. The fluid path FP of the cleaning liquid sprayer 53 may be connected to the cleaning liquid supplier CS. A cleaning liquid supplied by the cleaning liquid supplier CS may move into the drain cup module 5 through the fluid path FP. The cleaning liquid supplied into the drain cup module 5 may flow to the outlet 51h of the cup body 51. More specifically, the cleaning liquid may flow from an upper portion of the drain cup module 5 (for example, the cleaning liquid sprayer 53) to a lower portion (for example, the cup body 51) along an inner wall of the drain cup module 5. Accordingly, the drain cup module 5 may be also cleaned with the spray nozzle 451 of FIG. 4 by using the cleaning liquid.

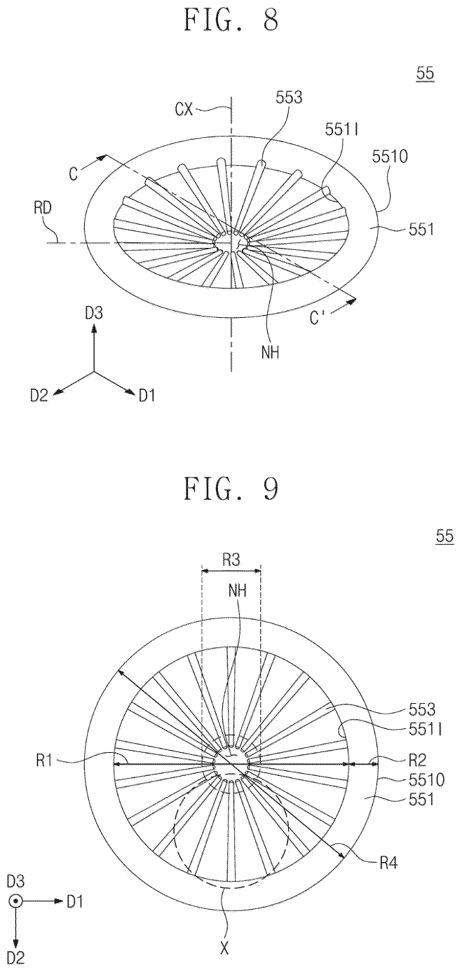

The sealing member 55 may connect the cup body 51 and the cleaning liquid sprayer 53. More specifically, the sealing member 55 may seal a gap between the cup body 51 and the cleaning liquid sprayer 53. Accordingly, the cleaning liquid supplied to the inside of the drain cup module 5 may be prevented from being pushed out to an outside of the drain cup module 5. In addition, the processing liquid sprayed by the spray nozzle 451 may be prevented from being pushed out to the outside of the drain cup module 5. Description for the sealing member 55 will be made later with reference to FIGS. 8 to 10 in detail.

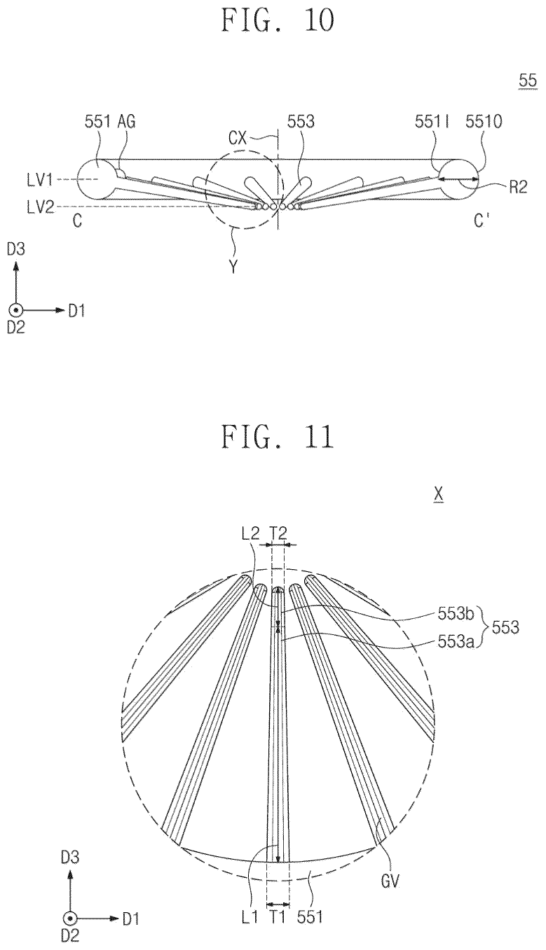

FIG. 8 is a perspective view illustrating a sealing member of a drain cup module according to one or more embodiments. FIG. 9 is a plan view illustrating a sealing member of a drain cup module according to one or more embodiments. FIG. 10 is a cross-sectional view taken along line C-C′ of FIG. 8 illustrating a sealing member of a drain cup module according to one or more embodiments.

Referring to FIGS. 8, 9 and 10, the sealing member 55 may be provided. For example, the sealing member 55 may include perfluoroelastomer (FFKM), but embodiments are not limited thereto. The sealing member 55 may include an O-ring 551 and brushes 553.

The O-ring 551 may be a rotator having a central axis CX parallel to the third direction D3 and passing through a center thereof. That is, the central axis CX may be perpendicular to or intersect a radial direction RD of the O-ring that extends toward an inside of the O-ring. For example, the O-ring 551 may have a shape of a ring having the central axis CX as the center. The O-ring 551 may have an inside 551I and an outside 551O. The inside 551I of the O-ring 551 may face the central axis CX. The outside 551O of the O-ring 551 may be opposed to the inside 551I, and may not face the central axis CX.

The O-ring 551 may have an inner diameter R1, a cross-sectional diameter R2 and an outer diameter R4. The inner diameter R1 of the O-ring 551 may refer to a maximum distance of the inside 551I of the O-ring 551. The cross-sectional diameter R2 of the O-ring 551 may be a diameter of a cross-section of the O-ring 551. The outer diameter R4 of the O-ring 551 may refer to a maximum distance from the outside 551O of the O-ring 551. For example, the inner diameter R1 of the O-ring 551 may be about 40 mm to about 50 mm. The cross-sectional diameter R2 of the O-ring 551 may be about 1 mm to about 3 mm. The outer diameter R4 of the O-ring 551 may be a sum of the inner diameter R1 and two cross-sectional diameters R2.

The brushes 553 may be located on the inside 551I of the O-ring 551. The brushes 553 may be disposed in a circumferential direction of the central axis CX of the O-ring 551. In addition, the brushes 553 may be spaced apart from each other so as to not contact each other, but embodiments are not limited thereto. Each of the brushes 553 may have a form protruding from the inside 551I of the O-ring 551. More specifically, each of the brushes 553 may extend from the inside 551I of the O-ring 551 toward the central axis CX of the O-ring 551. For example, each of the brushes 553 may have a shape of a bar or line. Each of the brushes 553 may include a portion contacting the O-ring 551 and an end portion adjacent to the central axis CX.

More specifically, each of the brushes 553 may extend in a direction not parallel to the first direction D1 and the second direction D2 (e.g., an off-axis direction with respect to D1 and D2). For example, an angle AG between each of the brushes 553 and the inside 551I of the O-ring 551 may be about 100° to about 110°. In other words, the angle AG between a line horizontally extending across the O-ring 551 in a cross-sectional view and a line corresponding to the extension of the brushes 553 may be about 100° to about 110°. That is, each of the brushes 553 may extend in an inclined direction. In other words, a second level LV2 of the end portion of each of the brushes 553 may be lower than a first level LV1 of the O-ring 551. The first level LV1 of the O-ring 551 may refer to a height (or location) of the center of the O-ring 551 along the third direction D3, and the second level LV2 of the end portion of each of the brushes 553 may refer to a height (or location) of the end portion of a brush or brushes 533 along the third direction D3. Accordingly, the cleaning liquid may flow along the brushes 553 in the substrate processing method to be described later.

In addition, a length of each of the brushes 553 may be smaller than an inner radius (for example, a half of the inner diameter R1) of the O-ring 551. The brushes 553 opposed to each other may not contact each other. Each of the brushes 553 may not pass through the central axis CX of the O-ring 551. A nozzle hole NH surrounded by the end portions of the brushes 553 may be formed. For example, the spray nozzle 451 described with reference to FIG. 4 may be inserted into the nozzle hole NH. The nozzle hole NH may be smaller than a diameter R3 of the spray nozzle 451 of FIG. 4. Accordingly, in a process of inserting the spray nozzle 451 of FIG. 4 into the nozzle hole NH, a portion of each of the brushes 553 and the spray nozzle 451 of FIG. 4 may contact each other.

According to one or more embodiments, the O-ring 551 and the brushes 553 may be configured as a single object. In this case, the O-ring 551 and the brushes 553 may include the same material, and may not be separated from each other.

According to one or more embodiments the O-ring 551 and the brushes 553 may not be configured as the single object. The O-ring 551 and the brushes 553 may include different materials. In addition, the O-ring 551 and the brushes 553 may be separated from each other. In this case, the brushes 553 may be periodically replaced.

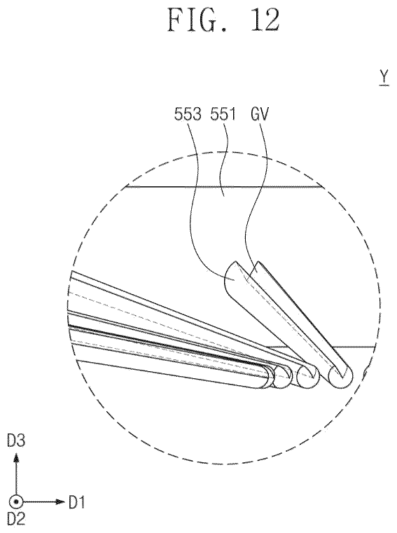

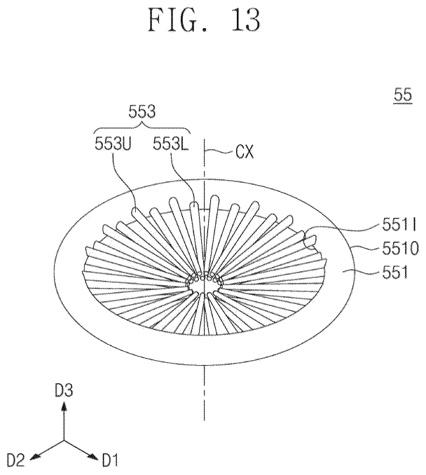

FIG. 11 is an enlarged diagram of region X of FIG. 9 according to one or more embodiments. FIG. 12 is an enlarged diagram of region Y of FIG. 10 according to one or more embodiments.

Referring to FIGS. 11 and 12, the brushes 553 protruding from the O-ring 551 may be provided. Each of the brushes 553 may include a first portion 553a and a second portion 553b.

The first portion 553a of each of the brushes 553 may contact the O-ring 551, and may extend in one direction. The first portion 553a may have a first length L1 in the extension direction. For example, the first length L1 of the first portion 553a may be about 15 mm to about 20 mm. In addition, the first portion 553a may have a thickness in a direction crossing the first length L1. The first portion 553a may have a first thickness T1 in a portion adjacent to the O-ring 551. For example, the first thickness T1 of the first portion 553a may be about 1 mm to about 3 mm.

The second portion 553b of each of the brushes 553 may be spaced apart from the O-ring 551, and may be adjacent to the central axis CX of the O-ring 551 described with reference to FIGS. 8 to 10. The second portion 553b may have a second length L2 in the same direction as the first length L1 of the first portion 553a. For example, the second length L2 of the second portion 553b may be about 2 mm to about 5 mm. The second portion 553b may have a second thickness T2 in the same direction as the first thickness T1 of the first portion 553a. For example, the second thickness T2 of the second portion 553b may be about 1 mm to about 3 mm.

According to one or more embodiments, the first thickness T1 of the first portion 553a may be greater than the second thickness T2 of the second portion 553b. For example, each of the brushes 553 may have a thickness decreasing in a direction getting farther from the O-ring 551. That is, a thickness of each of the brushes 553 may decrease in a radial direction toward the central axis CX of FIG. 8. The thickness of each of the brushes 553 may be relatively thick in a portion supported by the O-ring 551, and may be relatively thin in a portion contacting the spray nozzle 451. Accordingly, durability of the brushes 553 may be increased.

According to one or more embodiments, the second portion 553b may have a convex form. For example, the second portion 553b may be convex toward the central axis CX of FIG. 8. The second portion 553b may correspond to the end portion of each of the brushes 553 that contacts the spray nozzle 451 of FIG. 4 described above. That is, each of the brushes 553 may include the end portion in which an end thereof that is convex. Accordingly, the brushes 553 may minimize a damage inflicted on the spray nozzle 451 of FIG. 4.

Each of the brushes 553 may have a groove GV extending therein. The groove GV may extend along the brushes 553. For example, the groove GV may be provided in the first portion 553a and the second portion 553b of each of the brushes 553. In other words, the groove GV of each of the brushes 553 may extend from the O-ring 551 toward the central axis CX of FIG. 8.

In addition, the groove GV may be disposed such that an opened portion thereof faces upward. For example, the groove GV may be a groove formed in an upper portion of each of the brushes 553. Accordingly, the groove GV may face an upper end of the sealing member 55. The groove GV may have a cross-sectional shape of V, but embodiments are not limited thereto. For example, the groove GV may have a cross-sectional shape of U, a circle, an ellipsoid, a polygon, and the like.

FIG. 13 is a perspective view illustrating a sealing member of a drain cup module according to one or more embodiments.

Referring to FIG. 13, the sealing member 55 including the brushes 553 being positioned at different levels may be provided. The sealing member 55 may include the O-ring 551 and the brushes 553, and the brushes 553 may include lower brushes 553L and upper brushes 553U. The O-ring 551 may be substantially the same as what is described with reference to FIGS. 8 to 10, and repeated descriptions thereof may be omitted.

The lower brushes 553L and the upper brushes 553U may be located on the inside 551I of the O-ring 551. The lower brushes 553L and the upper brushes 553U may have the substantially same structure as each other. For example, as described with reference to FIGS. 11 and 12, each of the lower brushes 553L and the upper brushes 553U may extend in one direction, may include a convex end portion, and may have a groove therein.

The upper brushes 553U may be located on the lower brushes 553L. Each of the upper brushes 553U may be located at a higher level than each of the lower brushes 553L. In a plan view, the upper brushes 553U and the lower brushes 553L may not overlap each other. That is, the upper brushes 553U and the lower brushes 553L may be horizontally and/or radially spaced apart from each other. For example, any one of the lower brushes 553L may be located between two adjacent upper brushes 553U. In other words, the lower brushes 553L and the upper brushes 553U may be disposed on the inside 551I of the O-ring 551 in a zigzag form.

According to one or more embodiments, middle brushes may be further provided between the lower brushes 553L and the upper brushes 553U. On a plan view, the middle brushes may be disposed so as not to overlap the lower brushes 553L and the upper brushes 553U.

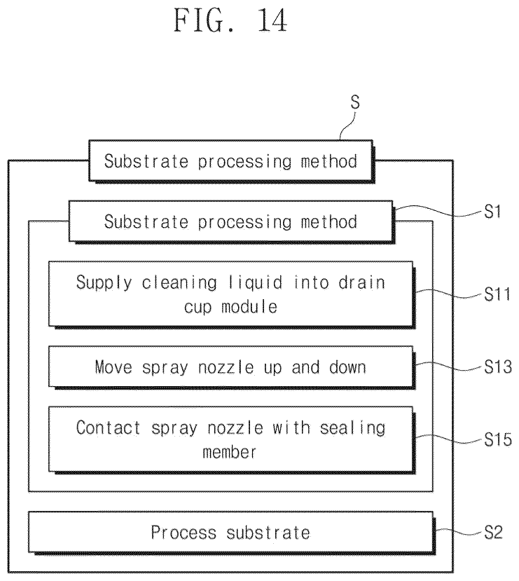

FIG. 14 is a flowchart illustrating a substrate processing method according to one or more embodiments.

Referring to FIG. 14, a substrate processing method S is shown. The substrate processing method S may be a method for processing a substrate using the drain cup module 5, the substrate wetting apparatus B including the same, and the substrate processing system P including the same, which are described with reference to FIGS. 1 to 13. The substrate processing method S may include operation S1 of cleaning the spray nozzle and operation S2 of processing the substrate.

Operation S1 of cleaning the spray nozzle may include operation S1) of supplying the cleaning liquid into the drain cup module, operation S13 of moving the spray nozzle up and down and an operation S15 of contacting the spray nozzle with the sealing member.

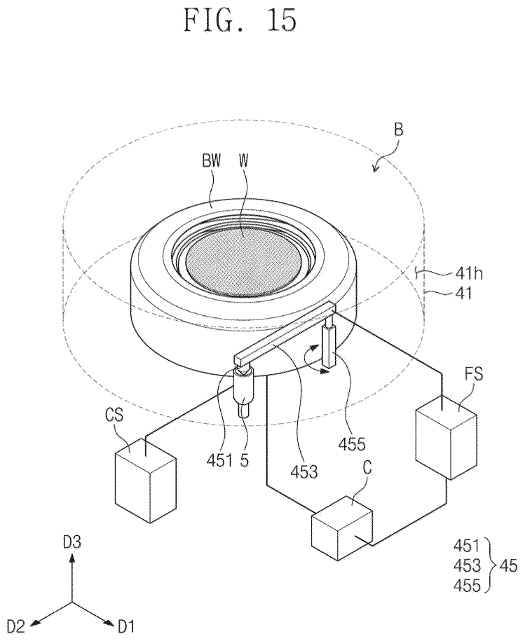

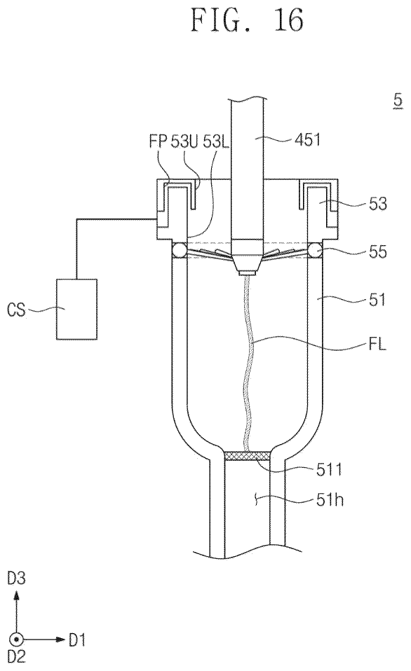

Hereinafter, the substrate processing method S will be described with reference to FIGS. 15 to 18 in more detail.

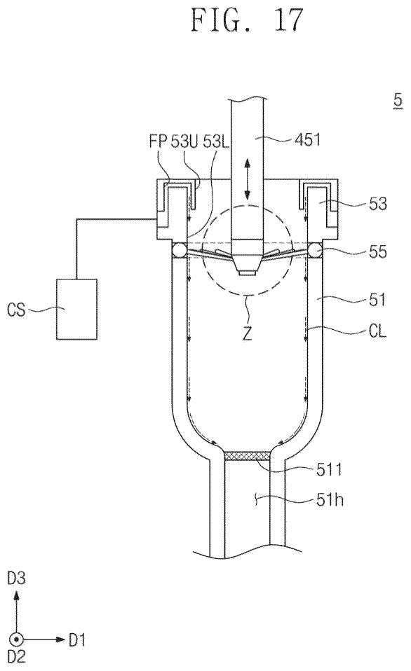

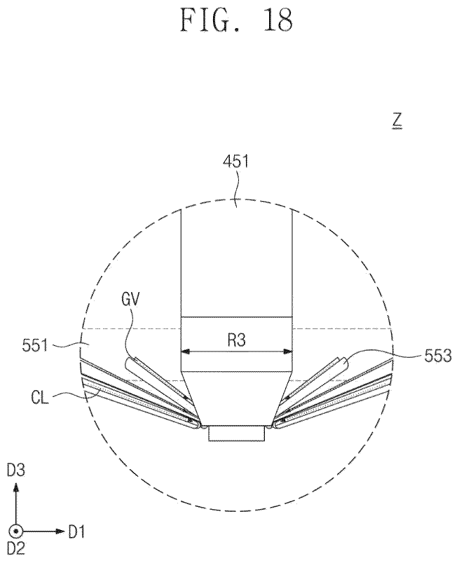

FIGS. 15 to 18 are diagrams illustrating a substrate processing method according to one or more embodiments. FIG. 15 is a perspective view illustrating the substrate wetting apparatus, FIGS. 16 and 17 are diagrams for describing an inside of the drain cup module, and FIG. 18 is an enlarged diagram of region Z of FIG. 17.

Referring to FIGS. 14 and 15, operation S1 of cleaning the spray nozzle may be performed by the drain cup module 5 of the substrate wetting apparatus B. For this, the spray nozzle 451 may be inserted into the drain cup module 5.

More specifically, operation S1 of cleaning the spray nozzle may include an operation of inserting the spray nozzle 451 into the drain cup module 5. The spray nozzle 451 may move in a horizontal direction by the nozzle mover 455 of the processing liquid sprayer 45 to be located on the drain cup module 5. Thereafter, the spray nozzle 451 may move in a vertical direction by the nozzle mover 455 to be inserted into the drain cup module 5.

FIGS. 14 and 16, operation S1 of cleaning the spray nozzle may further include an operation of spraying the processing liquid FL remaining in the spray nozzle 451. The processing liquid FL remaining in the spray nozzle 451 may partially react with air to be formed as a fume. Accordingly, the substrate wetting apparatus B may be internally contaminated, and the processing liquid FL may not constantly maintain a state thereof. Accordingly, the processing liquid FL may constantly maintain the state thereof by spraying the processing liquid FL remaining in the spray nozzle 451 before operation S2 of processing the substrate. For example, the processing liquid FL remaining in the spray nozzle 451 may be sprayed for about 10 seconds.

The mesh 511 of the cup body 51 may prevented the processing liquid FL from being scattered into the inside of the cup body 51 in the operation of spraying the processing liquid FL remaining in the spray nozzle 451. In addition, the brushes 553 of the sealing member 55 described with reference to FIGS. 8 to 12 may prevent the processing liquid FL from being scattered to the outside of the drain cup module 5. Accordingly, contamination inside the substrate wetting apparatus B caused by the processing liquid FL may be prevented.

Referring to FIGS. 14, 17 and 18, operation S11 of supplying the cleaning liquid into the drain cup module may be performed by the cleaning liquid supplier CS and the cleaning liquid sprayer 53. The cleaning liquid supplier CS may supply the cleaning liquid CL to the cleaning liquid sprayer 53. The cleaning liquid CL may move to the inside of the drain cup module 5 through the fluid path FP of the cleaning liquid sprayer 53. The fluid path FP may be configured such that the cleaning liquid CL flows along the inner wall of the drain cup module 5. The cleaning liquid CL may remove the processing liquid remaining on the inner wall of the drain cup module 5. For example, the cleaning liquid CL may include a liquid such as DI water.

Operation S13 of moving the spray nozzle up and down may be performed by the nozzle mover 455 of the processing liquid sprayer 45. The spray nozzle 451 may be moved relative to the sealing member 55 (e.g., vertically up and down with respect to the sealing member 55 in direction D3), but the translation movement of the spray nozzle 451 may vary depending on the alignment of components, such as the drain cup module 5. The nozzle mover 455 may move the spray nozzle 451 not only in the horizontal direction but also in the vertical direction. The spray nozzle 451 may move up or down in a direction parallel to the third direction D3 by the nozzle mover 455. Referring to FIG. 9 together, the diameter R3 of the spray nozzle 451 may be greater than a diameter of the nozzle hole NH. Accordingly, the spray nozzle 451 may partially contact the sealing member 55. That is, since the spray nozzle 451 moves up and down, the spray nozzle 451 and the sealing member 55 may contact each other.

Operation S15 of contacting the spray nozzle with the sealing member may include an operation of contacting the brushes 553 of the sealing member 55 with the spray nozzle 451. More specifically, when the spray nozzle 451 moves up and down, the spray nozzle 451 may partially contact the brushes 553 of the sealing member 55. Referring to FIG. 11 together, the spray nozzle 451 may be spaced apart from the first portion 553a of each of the brushes 553, and may contact the second portion 553b. Since the second portion 553b has a shape that is convex toward the spray nozzle 451, a damage inflicted to the spray nozzle 451 by the sealing member 55 may be minimized.

In addition, operation S15 of contacting the spray nozzle with the sealing member may include an operation of supplying the cleaning liquid CL to a surface of the spray nozzle 451. The cleaning liquid CL provided into the drain cup module 5 may flow along the inner wall of the drain cup module 5. The cleaning liquid CL may flow into the groove GV of each of the brushes 553 during passing through the sealing member 55. The cleaning liquid CL may flow along the groove GV of each of the brushes 553 to face the spray nozzle 451. That is, the sealing member 55 may not only physically contact the spray nozzle 451, but also supply the cleaning liquid CL to the surface of the spray nozzle 451. Accordingly, cleaning ability for the spray nozzle 451 may be improved.

According to one or more embodiments, operation S13 of moving the spray nozzle up and down may be repeated at least twice. The spray nozzle 451 may repeatedly move up and down. Accordingly, the spray nozzle 451 and the sealing member 55 may be repeatedly contacted to each other. Accordingly, contamination materials present on the surface of the spray nozzle 451 may be easily removed.

According to one or more embodiments, operation S13 of moving the spray nozzle up and down and operation S15 of contacting the spray nozzle with the sealing member may be further performed after operation S11 of supplying the cleaning liquid into the drain cup module. That is, while the spray nozzle 451 moves up and down without supplying the cleaning liquid CL, the spray nozzle 451 may contact the sealing member 55. Accordingly, the cleaning liquid CL remaining on the surface of the spray nozzle 451 may be removed by the brushes 553 of the sealing member 55. Accordingly, the cleaning liquid CL remaining on the surface of the spray nozzle 451 may be prevented from contaminating the substrate.

Referring back to FIGS. 1 to 5 and 14 together, operation S2 of processing the substrate may include an operation of wet-processing the substrate, an operation of transferring the wet-processed substrate, and an operation of dry-processing the wet-processed substrate.

The operation of wet-processing the substrate may include an operation of disposing the substrate W in the substrate wetting apparatus B, and an operation of spraying the processing liquid on the substrate W disposed on the substrate wetting apparatus B. The operation of disposing the substrate W in the substrate wetting apparatus B may include an operation of disposing the substrate W on the wetting stage 43. Thereafter, the spray nozzle 451 may be located on the substrate W disposed on the wetting stage 43. When the spray nozzle 451 sprays the processing liquid on the substrate W, the substrate W may rotate. That is, the wetting stage 43 may rotate by the rotational axis 47 to rotate the substrate W. Accordingly, the processing liquid sprayed on the substrate W may cover the surface of the substrate W by a centrifugal force thereof.

The operation of transferring the wet-processed substrate may be performed by the transfer apparatus TU of the substrate processing system P. For example, the transfer apparatus TU may move the substrate W disposed in the substrate wetting apparatus B to the substrate drying apparatus A.

The operation of dry-processing the substrate may include an operation of disposing the substrate W in the substrate drying apparatus A, and an operation of supplying the super-critical fluid on the substrate W disposed in the substrate drying apparatus A. The operation of disposing the substrate W in the substrate drying apparatus A may include an operation of disposing the substrate W on the drying stage 23. The super-critical fluid may be sprayed onto the substrate W disposed on the drying stage 23. The processing liquid applied to the substrate W may be removed by the super-critical fluid. During this operation, contamination particles present on the substrate W may be removed together.

According to one or more embodiments, operation S1 of cleaning the spray nozzle may be performed before operation S2 of processing the substrate. More specifically, operation S1 of cleaning the spray nozzle may be performed before the operation of wet-processing the substrate. For example, whenever the substrate is wet-processed, the spray nozzle 451 may be cleaned to be maintained in a constant state. That is, operation S1 of cleaning the spray nozzle and the operation of wet-processing the substrate may be alternately repeatedly performed.

According to one or more embodiments, when operation S2 of processing the substrate is not performed for a certain time, operation S1 of cleaning the spray nozzle may be performed. More specifically, when an idle time of the substrate wetting apparatus B is long (e.g., greater than a predetermined time threshold), operation S1 of cleaning the spray nozzle may be performed. For example, when the idle time of the substrate wetting apparatus B is equal to or longer than about 10 minutes, operation S1 of cleaning the spray nozzle may be performed. Accordingly, a fume may be prevented from occurring by the processing liquid remaining in the spray nozzle 451.

A drain cup module according to one or more embodiments and a substrate wetting apparatus including the same may include an O-ring and brushes extending from the O-ring. The brushes may improve cleaning ability for a spray nozzle by contacting the spray nozzle of the substrate wetting apparatus, and supplying a cleaning liquid to a surface of the spray nozzle. In addition, the brushes may remove the cleaning liquid remaining on the surface of the spray nozzle to prevent a substrate from being contaminated.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A drain cup module comprising:
a cup body comprising an outlet at a lower portion thereof;
a cleaning liquid sprayer on the cup body, and comprising an open upper end and an open lower end; and
a sealing member between the cup body and the cleaning liquid sprayer,
wherein the sealing member comprises:
an O-ring contacting the cup body and the cleaning liquid sprayer, and having a central axis that intersects a radial direction extending toward an inside of the O-ring; and
a first brush extending from an inside of the O-ring in the radial direction toward the central axis.

2. The drain cup module of claim 1, wherein the first brush comprises an end portion that is convex toward the central axis.

3. The drain cup module of claim 2, wherein the end portion of the first brush is at a level that is lower than a level of the O-ring.

4. The drain cup module of claim 1, wherein a thickness of the first brush decreases in the radial direction toward the central axis of the O-ring.

5. The drain cup module of claim 1, wherein the sealing member further comprises a second brush that is at a level that is lower than the first brush.

6. The drain cup module of claim 5, wherein the first brush is spaced apart from the second brush in a circumferential direction with respect to the central axis.

7. The drain cup module of claim 1, wherein the first brush comprises a groove therein that extends toward the central axis.

8. The drain cup module of claim 1, wherein the sealing member further comprises a plurality of brushes comprising the first brush, and
wherein the plurality of brushes are disposed around the central axis in a circumferential direction with respect to the central axis.

9. The drain cup module of claim 1, wherein a length of the first brush is smaller than an inner radius of the O-ring.

10. A substrate wetting apparatus comprising:
a wet stage configured to support a substrate;
a spray nozzle configured to supply a processing liquid on the substrate; and
a drain cup module spaced apart from the wet stage,
wherein the drain cup module comprises:
a cup body comprising an outlet at a lower portion thereof;
a cleaning liquid sprayer on the cup body; and
a sealing member between the cup body and the cleaning liquid sprayer, and
wherein the spray nozzle is configured to contact the sealing member.

11. The substrate wetting apparatus of claim 10, wherein the sealing member comprises:
an O-ring contacting the cup body and the cleaning liquid sprayer; and
a first brush protruding from an inside of the O-ring.

12. The substrate wetting apparatus of claim 11, wherein a length of the first brush is smaller than an inner radius of the O-ring.

13. The substrate wetting apparatus of claim 11, wherein the O-ring has ring shape having a central axis extending through a center of the ring shape, and
the first brush comprises an end portion that is convex toward the central axis.

14. The substrate wetting apparatus of claim 11, wherein the first brush comprises a groove therein, and
wherein the groove is configured such that a cleaning liquid supplied by the cleaning liquid sprayer flows along the groove.

15. The substrate wetting apparatus claim 11, wherein an angle between the first brush and a line horizontally extending across the O-ring in a cross-sectional view is 100° to 110°.

16. A drain cup module, comprising:
a cup body;
a cleaning liquid sprayer on the cup body and configured to receive a spray nozzle of a substrate wetting apparatus;
an O-ring between the cup body and the cleaning liquid sprayer, the O-ring having a central axis that intersects a radial direction extending toward an inside of the O-ring; and
at least one brush extending from an inner circumference of the O-ring toward the central axis of the O-ring,
wherein at least one of the at least one brush comprises a groove therein that is configured such that cleaning liquid supplied by the cleaning liquid sprayer flows along the groove and toward the spray nozzle of the substrate wetting apparatus.

17. The drain cup module of claim 16, wherein the at least one brush comprises a first brush at a first level and a second brush at a second level that is lower than the first level.

18. The drain cup module of claim 16, wherein a thickness of the at least one brush decreases in the radial direction toward the central axis of the O-ring.

19. The drain cup module of claim 16, wherein the at least one brush comprises a first portion contacting the O-ring, and a second portion spaced apart from the O-ring and adjacent to the central axis of the O-ring, and
wherein a thickness of the first portion is greater than a thickness of the second portion.

20. The drain cup module of claim 16, wherein the groove comprises a V-shape.
